(19) United States
(12) Patent Application Publication
(10) Pub. No.: US 2016/0368763 A1
(43) Pub. Date: Dec. 22, 2016

(54) METHOD FOR PRODUCING A MICROMECHANICAL COMPONENT

(71) Applicant: ROBERT BOSCH GMBH, Stuttgart (DE)

(72) Inventors: Julian Gonska, Reutlingen (DE); Mawuli Ametowobla, Stuttgart (DE); Jochen Reinmuth, Reutlingen (DE)

(21) Appl. No.: 15/117,854

(22) PCT Filed: Dec. 22, 2014
(86) PCT No.: PCT/EP2014/078998

§ 371 Date: Aug. 10, 2016

(30) Foreign Application Priority Data
Feb. 17, 2014 (DE) 10 2014 202 801.9

(51) Int. Cl. B81C 1/00; B81B 1/00

(52) U.S. Cl. CPC B81C 1/00119; B81B 1/004; B81B 2203/0315; B81C 2203/0109; B81C 2203/019; B81C 2201/115; B81C 2201/112

(57) ABSTRACT

A method for manufacturing a micromechanical component including forming an access opening in an MEMS element or in a cap element of the component; connecting the MEMS element to the cap element, at least one cavity being formed between the MEMS element and the cap element; and closing off the access opening with respect to the at least one cavity under a defined atmosphere, using a laser.

### FIELD

The present invention relates to a method for manufacturing a micromechanical component. The present invention further relates to a micromechanical component.

### BACKGROUND INFORMATION

The existing art includes doping methods for silicon semiconductor components in which a thin layer having dopant-containing material is applied onto a monocrystalline silicon surface. The material on the surface is then melted to a shallow depth via a laser pulse. The melting depth depends here in particular on a wavelength of the laser radiation that is used, and on its application duration. With suitable process management the silicon is once again monocrystalline after solidification, and the specified dopant atoms are incorporated into the silicon lattice.

German Patent Application No. DE 195 37 814 A1 describes a method for manufacturing rotation rate sensors and acceleration sensors, in which method a plurality of free-standing, thick, polycrystalline functional structures are produced on a substrate. Buried conductor paths and electrodes are disposed below the functional structures.

Micromechanical structures produced in this manner are usually sealed with a cap wafer later in the process sequence. Depending on the application, a suitable pressure is enclosed inside the closed-off volume.

For rotation rate sensors, a very low pressure is enclosed in this context, typically approx. 1 mbar. The background is that with these sensors, a portion of the movable structure is driven resonantly, the intention being to excite a vibration with relatively low electrical voltages because there is little damping at low pressure.

For acceleration sensors, conversely, it is generally not desirable for the sensor to vibrate, which would be possible upon application of an external acceleration. Acceleration sensors are therefore operated with higher internal pressures, typically approx. 500 mbar. In addition, the surfaces of movable structures of such sensors are often provided with organic coatings that are intended to prevent the aforesaid structures from adhering to one another.

If very small and inexpensive combinations of rotation rate sensors and acceleration sensors are to be manufactured, this can be done by providing both a rotation rate sensor and an acceleration sensor on one semiconductor component. The two sensors are manufactured simultaneously on one substrate. The sensors are encapsulated at the substrate level by way of a cap wafer that provides two cavities per semiconductor component.

The different pressures that are required in the cavities of the rotation rate sensor and of the acceleration sensor can be achieved, for example, by using a getter, a getter being disposed locally in the cavity of the rotation rate sensor. Firstly a high pressure is enclosed in both cavities. Then the getter is activated by way of a temperature step, with the result that the getter pumps the cavity volume above the rotation rate sensor to a low pressure. The aforesaid getter process disadvantageously requires, however, a mixture of an inert gas with a non-inert gas, as well as the relatively expensive getter layer that needs to be not only deposited but also patterned, and as a result is relatively complex and expensive.

In addition to the problem of furnishing two cavities having different pressures within one component, it is often difficult to achieve a low internal pressure inexpensively in only one cavity without using a getter or another additional step. Depending on the design, however, this can be very important for rotation rate sensors. Sealing of the microelectromechanical system (MEMS) element with a cap wafer is usually accomplished at high temperatures, using either a seal-glass as connecting material or using various other bonding materials or bonding systems, such as eutectic aluminum-germanium systems or copper-zinc-copper systems. The bonding method is preferably carried out under vacuum. The MEMS element is sealed, however, at high temperature (approx. 400° C. or higher), which can have the consequence that gases which vaporize out of the bonding system or out of the sensor wafer or cap wafer at this high temperature can cause in the MEMS element a residual pressure that is independent of the very low pressure in the bonding chamber during the bonding method.

A further problem in the context of closing off an MEMS element using a bonding method is that the aforementioned organic layers, which are intended to prevent the MEMS structures from adhering to one another, degrade at the high temperatures in the bonding method and are no longer fully effective. The degraded organic layers furthermore vaporize into the cavity and can undesirably raise the internal pressure there after closure of the MEMS sensor.

Methods for forming access holes in cavities, which are closed off with oxide, are conventional.

### SUMMARY

An object of the present invention is provide a method for improved manufacturing of a micromechanical component.

The object may be achieved according to a first aspect with an example method for manufacturing a micromechanical component having the following steps:
forming an access opening in an MEMS element or in a cap element of the component;
connecting the MEMS element to the cap element, at least one cavity being formed between the MEMS element and the cap element; and
closing off the access opening with respect to the at least one cavity under a defined atmosphere, using a laser.

The example method according to the present invention provides that in terms of time, firstly a connecting process between the MEMS element and the cap element is carried out, and a further processing step for the micromechanical component is carried out only thereafter, when the high temperature of the connecting process no longer exists. The subsequent further processing step, for example in the form of introduction of a defined internal pressure into a cavity, conditioning of a surface of MEMS structures, etc., can thus advantageously be carried out more flexibly and more inexpensively at a lower temperature.

According to a second aspect the object is achieved with a micromechanical component having:
a MEMS element capped with a cap element;
at least one cavity formed between the cap element and the MEMS element; and
an access opening, introduced into the cavity, which has been closed off under a defined atmosphere by way of a laser.

An advantageous refinement of the method in accordance with the present invention provides that a defined internal pressure is established in the cavity before closure. In this manner the cavity can be evacuated at low temperature and a defined internal pressure within the cavity can be established in simple fashion by subsequent closure.

An advantageous refinement of the method provides that the inclusion of the defined internal pressure in the cavity is carried out approximately at room temperature. Negative effects of a temperature gradient on pressure conditions within the cavity are thereby advantageously avoided, so that an internal pressure is retained in very stable fashion once established.

Advantageous refinements of the method provide that the access opening is formed either before or after connection of the MEMS element to the cap element. This advantageously assists flexible formation of the access opening.

A further advantageous refinement of the method provides that the access opening is embodied to be narrow, so that it can easily be closed off by way of a laser pulse. It can prove to be favorable for this purpose if a vertical depression, which is formed to be wider than the access opening and which faces toward the access opening, is provided in the cap or in the sensor. In such an assemblage the depth of the narrow region of the access opening can be reduced. Vertical channels having an aspect ratio (ratio of width to height or depth) of non-arbitrary magnitude can be etched using typical etching methods (trench methods), so that with such an assemblage, narrower access openings or access channels can be implemented for the same aspect ratio.

An advantageous refinement of the method provides that conditioning of a surface of MEMS structures of the MEMS element is carried out through the access opening. In this manner, after the connecting process a gaseous medium can be introduced into the cavity through the access opening, for example in the form of an organic anti-adhesion layer. The anti-adhesion layer is thereby advantageously not exposed to high temperature, and is not impaired in terms of its properties.

An advantageous refinement of the method provides that the conditioning encompasses roughening of the surface of the MEMS structures and/or deposition of a thin oxide layer onto the surface of the MEMS structures and/or deposition of an anti-adhesion layer onto the surface of the MEMS structures. A plurality of processing steps can thereby be carried out with low material impact at a low ambient temperature.

An advantageous refinement of the method provides that the enclosing of the defined internal pressure in the cavity is carried out approximately at room temperature. Outgassing can thereby advantageously be substantially avoided, the result being that a higher internal pressure can be enclosed in the cavity.

An advantageous refinement of the method provides that the access opening is formed by way of an etch stop on the sensor core of the MEMS element. Damage to or impairment of the sensitive sensor core of the micromechanical component can thereby advantageously be avoided.

An advantageous refinement of the method provides that the formation of the access opening provides for the formation of a partition wall with respect to the cavity, a connecting channel to the cavity being generated. Provision is thereby advantageously made, for the case in which particles are generated in the laser closure step, to avoid damage to the micromechanical structures by the particles. Efficient protection from vaporization is furthermore furnished in this manner.

An advantageous refinement of the method provides that the closing of the cavity is carried out by way of a pulsed laser or by way of an IR laser. It is possible as a result to carry out the method using different types of lasers which each have specific advantages.

An advantageous refinement of the method provides that the connecting of the MEMS element to the cap element is carried out by way of a bonding process or by way of a layer deposition process. The method according to the present invention is thereby, advantageously, universally usable for a bonding process with a cap wafer and for a thin-layer capping process for an MEMS element.

An advantageous refinement of the component according to the present invention is notable for the fact that the access opening and micromechanical structures of the MEMS element are disposed with a lateral offset from one another, a connecting channel being disposed between the access opening and the cavity. This advantageously assists substantial avoidance of damage to the sensor element by laser beams that, in the context of laser closing, are transported through the access opening before the silicon melts. Furthermore, any thermal stress on the component due to the introduced laser radiation can thereby also be minimized.

An advantageous refinement of the component is notable for the fact that the access opening extends into a sacrificial region in order to absorb vapor or particles that may occur as a result of closure of the access opening.

Advantageously, inexpensive closure of the micromechanical component, with low material impact, is furnished by way of the method. Closure can be carried out with no thermal stress on the component. Advantageously, the internal pressure of the micromechanical component is freely selectable, even very low internal pressures being possible. It is furthermore possible to enclose, freely selectably, gases and/or organic substances in the MEMS cavity. It is advantageously possible to provide on a single component several cavities having MEMS elements, in each of which a different internal pressure and/or a different gas or a different coating of the individual MEMS elements can be established.

Advantageously, the method according to the present invention is usable both for MEMS elements that are closed off using a bonding method with a cap wafer, and for MEMS structures that are closed off via layer deposition integrated into the MEMS process (called “thin layer capping”).

The present invention is described in further detail below with further features and advantages, with reference to several Figures. All features that are described, regardless of their presentation in the description and in the Figures, form the subject matter of the present invention. Identical or functionally identical elements have identical reference characters

### BRIEF DESCRIPTION OF THE DRAWINGS

FIG. 1 is a cross-sectional view of a conventional micromechanical component.

FIG. 2 is a cross-sectional view of a first embodiment of a micromechanical component according to the present invention.

FIG. 3 is a cross-sectional view of a further embodiment of the micromechanical component according to the present invention.

FIG. 4 is a cross-sectional view of a further embodiment of the micromechanical component according to the present invention.

FIG. 5 is a cross-sectional view of a further embodiment of the micromechanical component according to the present invention.

FIG. 6 schematically depicts the execution of an embodiment of the method according to the present invention.

### DETAILED DESCRIPTION OF EXAMPLE EMBODIMENTS

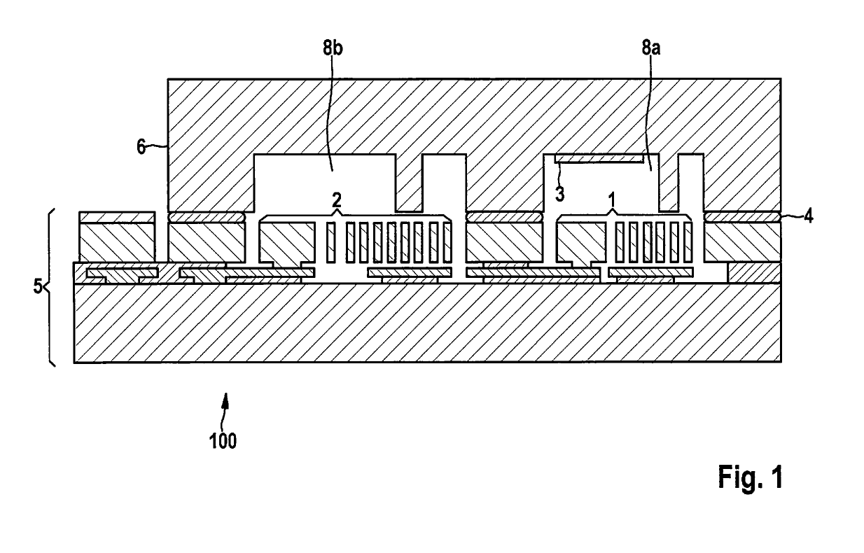

FIG. 1 is a cross-sectional view of a conventional micromechanical component 100 having an MEMS element 5 that has a first micromechanical sensor element 1 (e.g. a rotation rate sensor) and a second micromechanical sensor element 2 (e.g. an acceleration sensor). A cap element 6, in the form of a cap wafer formed preferably from silicon, is connected in bonded fashion to MEMS element 5 by way of bonding material 4. A cavity 8a, in which a defined internal pressure is enclosed, is formed above first sensor element 1. For a high-quality rotation sensor, a very low internal pressure is required for this purpose. A (for example, metallic) getter 3 disposed in cavity 8a takes on the task of creating the aforesaid defined internal pressure in cavity 8a of first sensor element 1.

A cavity 8b, in which a defined pressure is enclosed, is also disposed above second sensor element 2. The two sensor elements 1, 2 are disposed separately from one another beneath the shared cap element 6, and in this manner implement an inexpensive, space-saving micromechanical component 100 having a rotation rate sensor and an acceleration sensor.

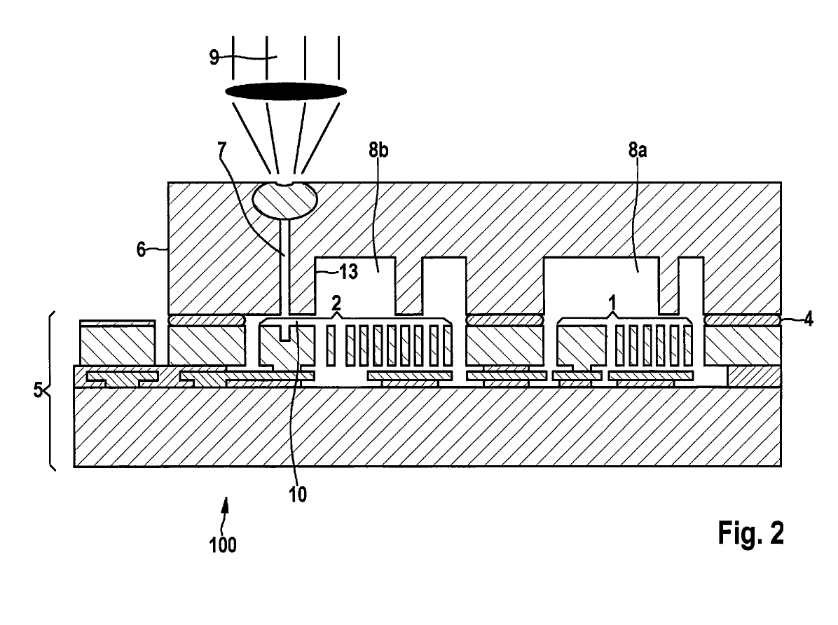

FIG. 2 shows a first embodiment of a micromechanical component 100 according to the present invention. It is evident that in addition to the structures of the conventional component 100 of FIG. 1, an access opening 7 into cavity 8b of second sensor element 2 is provided. A defined internal pressure inside cavity 8b of second sensor element 2 can be established or introduced via access opening 7. In addition, micromechanical structures of second sensor element 2 can be conditioned through access opening 7. This encompasses, for example, application of an organic, temperature-sensitive, highly water-repellent (for example, fluorine-containing) anti-adhesion layer, which is intended to prevent the movable MEMS structures of second sensor element 2 from sticking to one another.

Access opening 7 can alternatively be formed before or after the bonding of MEMS element 5 to cap element 6 has been carried out, and is closed off with a pulse of a laser 9 only after any optional conditioning of the MEMS structures of second sensor element 2 has been accomplished. In this context, silicon material of cap element 6 is briefly melted, with the result that access opening 7 becomes closed again with the material of cap element 6. A geometry of access opening 7 is preferably formed in such a way that access opening 7 becomes closed after melting by laser 9.

In the embodiment of FIG. 2 it is evident that access opening 7 etches in its vertical prolongation into a region of the sensor core of sensor element 2, although the latter is only insignificantly impaired thereby.

In addition to the directed etching into the sensor core, upon etching of access opening 7 an isotropic etching into the sensor core will also always occur to a certain extent as soon as the sensor core is opened with the etching process. It can therefore prove to be favorable, as depicted in FIG. 2, to dispose the region in which cap element 6 is opened, and the region in which the sensor core of second sensor element 2 is disposed, horizontally separately from one another, the two regions being connected only via a narrow connecting channel 10 formed beneath a partition wall 13.

What can be achieved thereby is that any silicon splinters that can split off due to the action of laser radiation in the process of closing off the cap element can be kept away, by partition wall 13, from the sensitive micromechanical structures of second sensor element 2.

In an embodiment not depicted in the figures, provision is made that along the aforesaid vertical prolongation of access opening 7, the sensor core can be equipped with an etch stop layer (e.g. made of aluminum) in order to prevent etching thereof.

Access opening 7 is preferably narrower than approx. 20 μm, typically on the order of approx. 10 μm.

In order to offer good gas exchange with respect to the MEMS structure and nevertheless to be effectively closable, access opening 7 can alternatively also be formed as a long slit.

The closing of access openings 7 or of the access slit can be carried out particularly favorably by way of a laser closure executed along a line (not depicted).

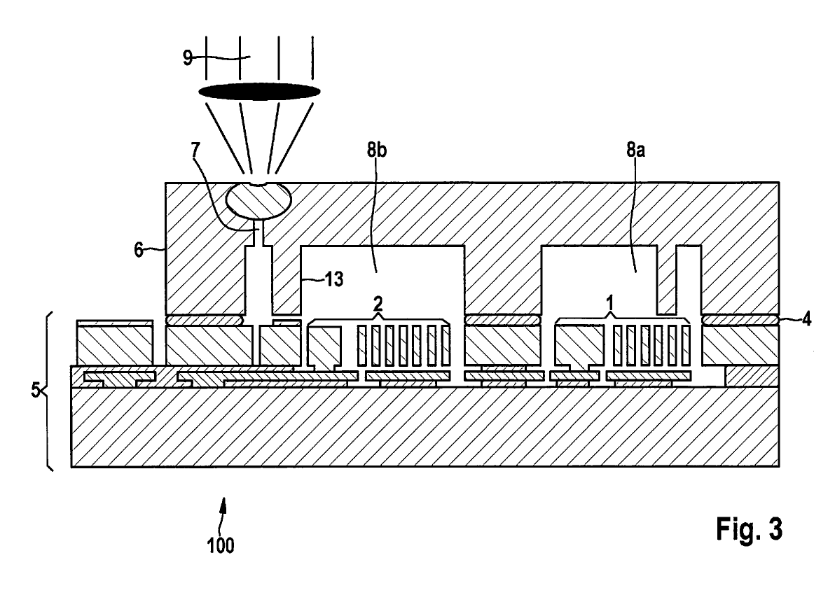

FIG. 3 shows a further embodiment of micromechanical component 100. With this variant it is evident that access opening 7 etches into the sensor core of second sensor element 2 in a region in which the latter is not damaged, since it is at a correspondingly large horizontal distance from second sensor element 2. It is further evident that access opening 7 has different widths that are formed in defined fashion by way of an aspect ratio of the etching operation, the narrow region of access opening 7 being directed toward the surface of cap element 6 so that access opening 7 can easily be closed off by way of laser 9.

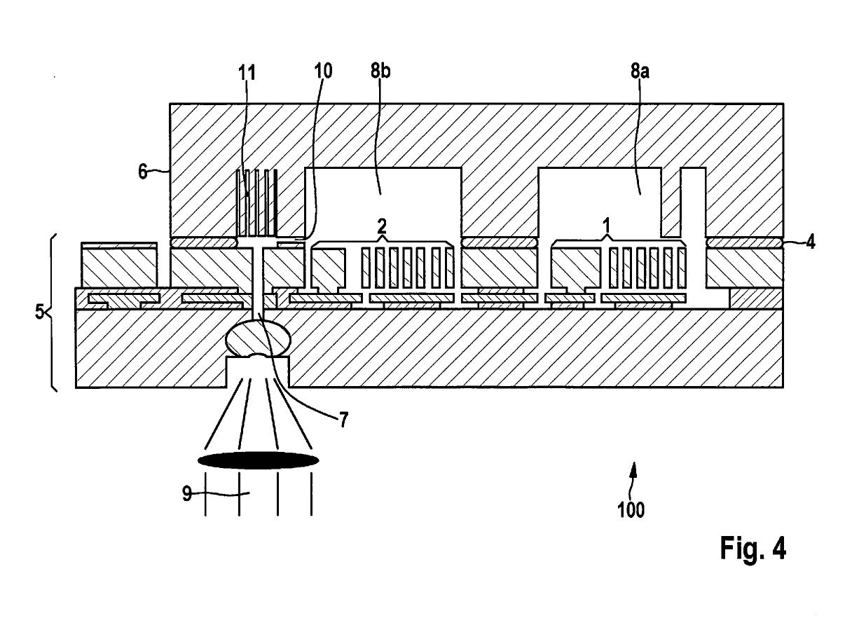

FIG. 4 is a cross-sectional view of a further embodiment of micromechanical component 100. It is evident that it can be favorable to provide, in a region of cap element 6 in which access opening 7 is located, a sacrificial region 11 having a large surface area by way of which the isotropic etching gas can be effectively dissipated, sacrificial region 11 being connected via a narrow horizontal connecting channel 10 to the sensor region of second sensor element 2. It is favorable in this case to introduce the etching channel for access opening 7 through the wafer of MEMS element 5 (“from below”).

In this case provision can be made, because of the aspect ratio of access opening 7, for the first portion of access opening 7 (proceeding from the surface of the wafer of the MEMS element) to be made relatively wide, and for a further portion, which extends into the sensor core of second sensor element 2, to be made relatively narrow. This advantageously assists good closability of the narrow region of access opening 7 using laser 9.

In the process of manufacturing MEMS element 5, the narrow access opening 7 can already be manufactured with the manufacturing processes used therefor. In the subsequent steps, the wide access opening can be put in place from the back side of the substrate of MEMS element 5.

Alternatively, as depicted in principle in FIG. 3 with reference to cap element 6, in order to maintain a flat surface on the substrate of MEMS element 5 it is also possible to place in the substrate firstly a wide cavity that is opened with a narrow access opening from the back side of the substrate (not depicted). This is favorable in particular when an ASIC circuit (not depicted), which is connected electrically to MEMS element 5 and serves as an evaluation circuit for MEMS element 5, is provided in cap element 6. Very compact sensor elements can thereby be manufactured.

It is favorable to use an infrared (IR) laser, having a wavelength of approx.>600 nm, to close off access openings 7 under a defined atmosphere. The infrared pulses of such lasers 9 penetrate particularly deeply into the silicon substrate and thereby enable particularly deep and reliable closure of access openings 7.

It can furthermore be favorable to use, as laser 9, a pulsed laser having a pulse length of less than approx. 100 μs with a power level, averaged over pulse times and off times, of less than 60 kW, in order to advantageously minimize thermal stress on the MEMS structures.

It can additionally be favorable, in the context of an access opening 7 formed with two different widths, to form the narrow region with more heavily doped silicon than the wide region, in order to achieve particularly high absorption of the laser power of laser 9 in that narrow region of access opening 7.

It can be favorable to provide more than one MEMS structure in at least two hermetically separated cavities 8a, 8b, and to close off at least one of cavities 8a, 8b with a laser pulse of laser 9. Different pressures can be established in cavities 8a, 8b. In this context, either the enclosed pressure is defined in first cavity 8a by the bonding method and in second cavity 8b by the laser closure process. Alternatively, the different internal pressures can each be implemented by way of a laser closure. Favorably, at least one acceleration sensor or rotation rate sensor or magnetic field sensor or pressure sensor is disposed respectively in the two separate cavities 8a, 8b.

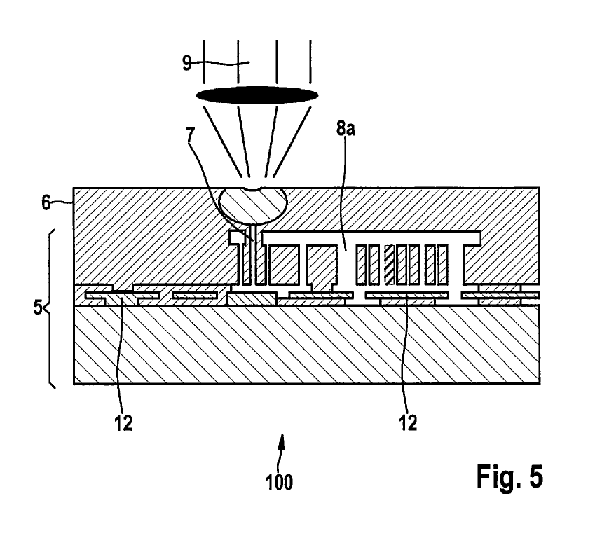

FIG. 5 shows schematically that the method according to the present invention can also be carried out in the context of an MEMS element 5 closed off by thin-layer capping. For this, firstly MEMS structures are produced on the substrate of MEMS element 5. The MEMS structures are then covered with an oxide layer (not depicted), and a cap element 6 in the form of a polysilicon layer is deposited over the oxide layer. At least one access opening 7 is then etched into the polysilicon layer of cap element 6. In a subsequent etching step the oxide layer is etched out using a gaseous etching gas (e.g. gaseous hydrogen fluoride, HF), and the MEMS structure of MEMS element 5 is disengaged.

Optionally, an organic anti-adhesion layer (not depicted) can be deposited through access openings 7, or other conditioning of the MEMS surface can be performed.

Under a defined atmosphere, access opening 7 is closed off again by way of laser pulses of laser 9. Lastly, contact regions 12 are applied for the purpose of electrical contacting to the MEMS structure.

In a variant, provision can be made that the oxide layer is opened in the region of access opening 7, and monocrystalline silicon is epitaxially grown there. Access opening 7 is placed in monocrystalline regions and closed with a laser pulse. In this case the closure is particularly simple to check optically, since depending on orientation, monocrystalline silicon forms a very smooth surface that can easily be checked optically by way of very high reflectivity and little scattered light.

The advantageous variants set forth above in conjunction with the cap wafer formed as cap element 6 can also be transferred to the thin-layer capping variant of micromechanical component 100.

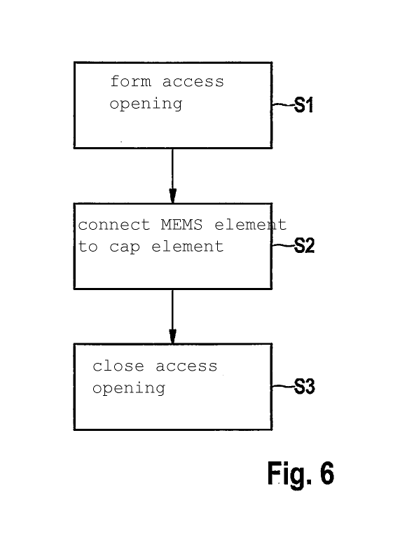

FIG. 6 schematically shows the execution of an embodiment of the method according to the present invention.

In a first step S1, an access opening 7 is formed in an MEMS element 5 or in a cap element 6 of component 100.

In a second step S2, connection of MEMS element 5 to cap element 6 is carried out, at least one cavity 8a, 8b being formed between MEMS element 5 and cap element 6.

Lastly, in a third step S3, closure of access opening 7 with respect to the at least one cavity 8a, 8b is carried out under a defined atmosphere using a laser 9.

In summary, the present invention furnishes a method with which it is advantageously possible to not furnish separate material for closing off a micromechanical component, closure being carried out substantially without temperature stress on the MEMS element.

The method according to the present invention makes it possible to provide, on a single component, several cavities having MEMS elements, in each of which a different internal pressure and/or a different gas and/or a different coating of movable MEMS structures of the individual MEMS elements can be respectively established or disposed.

Because the method according to the present invention, thanks to the action of the laser pulses, closes off silicon material using silicon material, the closure is very robust, tight, low-diffusion, and stable. The method moreover is advantageously inexpensive, since corresponding laser processes can be carried out very time-efficiently using scanning mirrors. A scanning rate of the scanning mirrors substantially determines how quickly the access openings can be closed off. Advantageously, expensive getter processes are not required for establishment of a defined pressure in the cavities, although the getter processes are still usable as necessary.

The example method in accordance with the present invention can thus be used, for example, in simplified manufacture of integrated acceleration sensors and rotation rate sensors. Increased functionality can thereby advantageously be implemented within a single micromechanical component or module. It is of course possible, for example, to apply the method according to the present invention only to one of several cavities or to each individual one of several cavities.

Although the present invention has been disclosed above with reference to concrete exemplifying embodiments, it is in no way limited thereto.

One skilled in the art will thus be able to appropriately modify the above-described features, or combine them with one another, without deviating from the essence of the present invention.

1-9. (canceled)

10. A method for manufacturing a micromechanical component, comprising:
forming an access opening in a MEMS element or in a cap element of the component;
connecting the MEMS element to the cap element, at least one cavity being formed between the MEMS element and the cap element; and
closing off the access opening with respect to the at least one cavity under a defined atmosphere, using a laser.

11. The method as recited in claim 10, further comprising:
establishing a defined internal pressure in the cavity before closing the access opening.

12. The method as recited in claim 10, further comprising:
conditioning a surface of MEMS structures of the MEMS element through the access opening.

13. The method as recited in claim 12, wherein the conditioning includes at least one of: i) roughening of the surface of the MEMS structures of the MEMS element, ii) depositing a thin oxide layer onto the surface of the MEMS structures of the MEMS element, and iii) depositing an anti-adhesion layer onto the surface of the MEMS structures of the MEMS element.

14. The method as recited in claim 10, wherein the formation of the access opening provides for a formation of a partition wall with respect to the cavity, a connecting channel to the cavity being generated.

15. The method as recited in claim 10, wherein the closing of the cavity is carried out one of: i) by way of a pulsed laser, or ii) by way of an IR laser.

16. The method as recited in claim 10, wherein the connecting of the MEMS element to the cap element is carried out one of: i) by way of a bonding process, or ii) by way of a layer deposition process.

17. A micromechanical component, comprising:
a MEMS element capped with a cap element;
at least one cavity formed between the cap element and the MEMS element; and
an access opening, introduced into the cavity, which has been closed off by way of a laser under a defined atmosphere.

18. The micromechanical component as recited in claim 17, wherein the access opening and micromechanical structures of the MEMS element are disposed with a lateral offset from one another, a connecting channel being disposed between the access opening and the cavity.
